(19) United States
(12) Patent Application Publication
(10) Pub. No.: US 2023/0335463 A1
(43) Pub. Date: Oct. 19, 2023

(54) HEAT RADIATING MEMBER AND SEMICONDUCTOR MODULE

(71) Applicant: Nidec Corporation, Kyoto (JP)

(72) Inventors: Yuki YANAGITA, Kyoto (JP); Koji MURAKAMI, Kyoto (JP)

(21) Appl. No.: 18/129,956

(22) Filed: Apr. 3, 2023

(30) Foreign Application Priority Data
Apr. 13, 2022 (JP) 2022-066391

(51) Int. Cl. H01L 23/473; F28F 3/04

(52) U.S. Cl. CPC H01L 23/473; F28F 3/048; F28F 2215/08; H01L 25/072

(57) ABSTRACT

A heat radiator includes a plate-shaped base portion that extends in a first direction along the flowing direction of a refrigerant and in a second direction perpendicular or substantially perpendicular to the first direction and has a thickness in a third direction and a fin protruding from the base portion toward one side in the third direction. The fin includes a flat plate-shaped sidewall that extends in the first direction and the third direction with the second direction being a thickness direction. The sidewall includes a protrusion protruding in the second direction. A protrusion amount of the protrusion in the second direction is equal to or less than half of an interval between the sidewalls of the fin adjacent in the second direction. The protrusion includes an opposing surface opposing the flowing direction of the refrigerant. The opposing surface has a rectangular or substantially rectangular shape extending from the sidewall.

### CROSS-REFERENCE TO RELATED APPLICATIONS

The present application claims priority under 35 U.S.C. § 119 to Japanese Patent Application No. 2022-066391, filed on Apr. 13, 2022, the entire contents of which are hereby incorporated herein by reference.

### 1. FIELD OF THE INVENTION

The present disclosure relates to a heat radiator.

### 2. BACKGROUND

Conventionally, a cooling device including a water jacket used for water cooling and a heat radiator is known. The heat radiator includes cooling fins. The fins are accommodated in the water jacket. The inside of the water jacket serves as a flow path of cooling water, and a heating element is water-cooled through the fins.

The heat radiator is required to improve the cooling performance. Furthermore, the heat radiator is required to suppress clogging with contamination included in cooling water.

### SUMMARY

A heat radiator according to an example embodiment of the present disclosure includes a plate-shaped base portion that extends in a first direction along the flowing direction of a refrigerant and in a second direction perpendicular or substantially perpendicular to the first direction and has a thickness in a third direction perpendicular or substantially perpendicular to the first direction and the second direction and a fin protruding from the base portion toward one side in the third direction. The fin includes a flat plate-shaped sidewall that extends in the first direction and the third direction with the second direction being a thickness direction. The sidewall is provided with a protrusion protruding in the second direction. A protrusion amount of the protrusion in the second direction is equal to or less than half of an interval between the sidewalls of the fin adjacent in the second direction. The protrusion includes an opposing surface opposing the flowing direction of the refrigerant. The opposing surface has a rectangular or substantially rectangular shape extending in the second direction from the sidewall.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view of a heat radiator according to an example embodiment of the present disclosure.

FIG. 2 is a side view of the heat radiator illustrated in FIG. 1.

FIG. 3 is an enlarged view of a region A in FIG. 1.

FIG. 4 is a plan sectional view of a fin according to an example embodiment of the present disclosure.

FIG. 5 is a plan sectional view of a fin according to a modification of an example embodiment of the present disclosure.

FIG. 6 is a side view of various types heat radiators according to example embodiments of the present disclosure.

FIG. 7 is a graph illustrating an example of the result of performing a simulation on a model having a configuration in which a protrusion is inclined at an inclination angle θ.

FIG. 8 is an enlarged view illustrating a modification of protrusions provided on a sidewall according to an example embodiment of the present disclosure.

FIG. 9 is a perspective view illustrating another modification of the protrusions according to an example embodiment of the present disclosure.

FIG. 10 is a perspective view illustrating another modification of the protrusions according to an example embodiment of the present disclosure.

FIG. 11 is a perspective view illustrating another modification of the protrusions according to an example embodiment of the present disclosure.

FIG. 12 is a side sectional view of various types heat radiators.

FIG. 13 is a graph illustrating an example of the result of performing a simulation on a model having a configuration in which a protrusion is inclined at an inclination angle θ.

FIG. 14 is a side cross-sectional view of a heat radiator according to a modification of an example embodiment of the present disclosure.

### DETAILED DESCRIPTION

Hereinafter, example embodiments of the present disclosure will be described with reference to the drawings.

In the drawings, with the first direction as an X direction, X1 indicates one side in the first direction, and X2 indicates the other side in the first direction. The first direction is a direction along a direction F in which a refrigerant W flows, and the downstream side is indicated by F1 and the upstream side is indicated by F2. The downstream side F1 is one side in the first direction, and the upstream side F2 is the other side in the first direction. With the second direction orthogonal to the first direction as a Y direction, Y1 indicates one side in the second direction, and Y2 indicates the other side in the second direction. With the third direction orthogonal to the first direction and the second direction as a Z direction, Z1 indicates one side in the third direction, and Z2 indicates the other side in the third direction. Note that the above-described “orthogonal” also includes intersection at an angle slightly shifted from 90°. Each of the above-described directions does not limit a direction when a heat radiator 5 is incorporated in various devices.

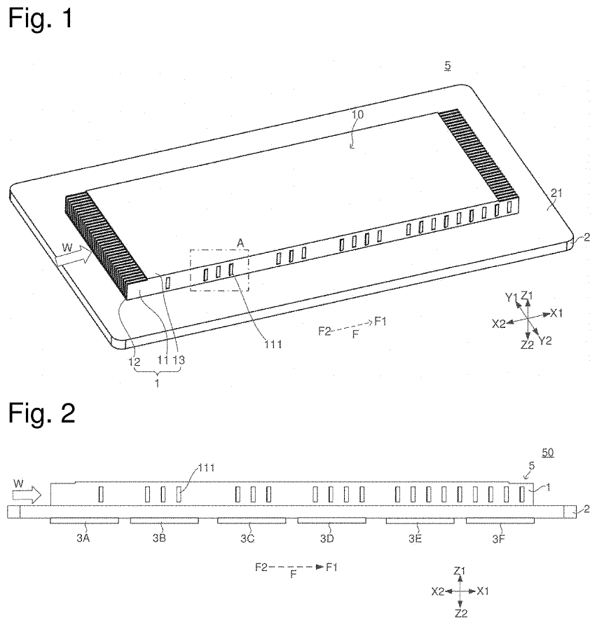

FIG. 1 is a perspective view of a heat radiator 5 according to an example embodiment of the present disclosure. FIG. 2 is a side view of the heat radiator 5. FIG. 2 is a view of the heat radiator 5 as viewed to one side in the second direction.

A cooling device includes the heat radiator 5 and a liquid cooling jacket (not illustrated) in which the heat radiator 5 is installed. The cooling device is a device for cooling a plurality of semiconductor devices 3A, 3B, 3C, 3D, 3E, and 3F (to be referred to as the semiconductor device 3A and the like) (see FIG. 2). The semiconductor device is an example of a heating element. The semiconductor device 3A and the like are power transistors of an inverter included in a traction motor for driving wheels of a vehicle, for example. The power transistor is, for example, an insulated gate bipolar transistor (IGBT). In this case, the cooling device is mounted on the traction motor. Note that the number of semiconductor devices may be plural other than six or may be one.

The heat radiator 5 includes a base portion 2 and a heat radiating fin portion 10. The base portion 2 has a plate shape that extends in the first direction and the second direction and has a thickness in the third direction. The base portion 2 is made of a metal having high thermal conductivity, for example, a copper alloy.

The heat radiating fin portion 10 is fixed to one side of the base portion 2 in the third direction. The heat radiating fin portion 10 is configured as a so-called stacked fin formed by arranging a plurality of fins 1 formed of one metal plate extending in the first direction in the second direction. The fin 1 is made of, for example, a copper plate.

The fin 1 includes a sidewall 11, a bottom plate portion 12, and a top plate portion 13. The sidewall 11 has a flat plate shape extending in the first direction and the third direction with the second direction being a thickness direction.

The bottom plate portion 12 is bent toward one side in the second direction at the third-direction other end portion of the sidewall 11. The top plate portion 13 is bent toward one side in the second direction at third-direction one end portion of the sidewall 11. Accordingly, a cross-section of the fin 1 has a rectangular U-shape. The heat radiating fin portion 10 having the fins 1 stacked in the second direction is fixed to the base portion 2 by fixing the bottom plate portion 12 to third-direction one side surface 21 of the base portion 2 by, for example, brazing. That is, the heat radiator 5 has the fins 1 protruding from the base portion 2 toward one side in the third direction.

The heat radiating fin portion 10 is accommodated in a liquid cooling jacket (not illustrated). As illustrated in FIG. 1, a refrigerant W flowing into the liquid cooling jacket flows into the heat radiating fin portion 10 from the other side (upstream side) in the first direction. The refrigerant W is, for example, water or an ethylene glycol aqueous solution. The refrigerant W flows to one side in the first direction inside the flow path formed between the fins 1 adjacent in the second direction, is discharged from the heat radiating fin portion 10, and is then discharged to the outside from the liquid cooling jacket. The semiconductor device 3A and the like are disposed on the other side of the base portion 2 in the third direction (see FIG. 2). Heat generated from the semiconductor device 3A and the like moves to the refrigerant W through the base portion 2 and the fins 1, whereby the semiconductor device 3A and the like are cooled. Note that a semiconductor module 50 includes the heat radiator 5 and the semiconductor device 3A and the like disposed on the other side of the base portion 2 in the third direction (see FIG. 2).

As illustrated in FIGS. 1 and 2, the fin 1 has the protrusions 111. A configuration related to the protrusion 111 will be described below. One protrusion 111 is disposed in the third direction and a plurality of protrusions are disposed in the first direction.

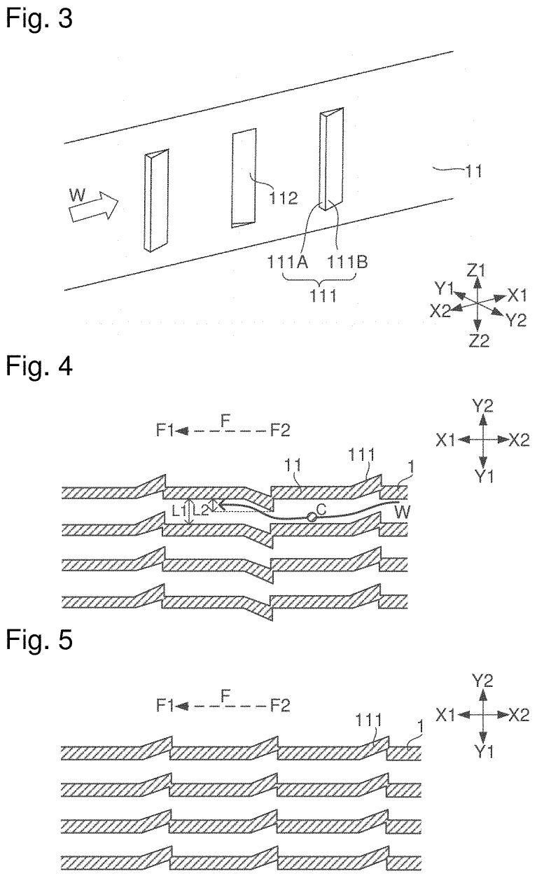

FIG. 3 is an enlarged view of a region A in FIG. 1. The protrusion 111 is provided on the sidewall 11 of the fin 1. The protrusion 111 protrudes from the sidewall 11 in the second direction. Referring to FIG. 3, the protrusions 111 closest to the other side in the first direction and closest to one side in the first direction protrude to the other side in the second direction. The protrusion 111 disposed between the protrusions 111 protrudes to one side in the second direction. That is, the protrusions 111 alternately protrude in the second direction toward the first direction. That is, the sidewall 11 is provided with the protrusion 111 protruding in the second direction.

As illustrated in FIG. 3, the protrusion 111 is formed in a triangular prism shape extending in the third direction. The protrusion 111 has an opposing surface 111A facing the direction in which the refrigerant W flows. The opposing surface 111A has a rectangular shape standing in the second direction from the sidewall 11. By providing the protrusion 111 on the sidewall 11, turbulence is generated in the flow near the sidewall 11, and the temperature boundary layer developed on the sidewall 11 is destroyed, whereby the heat transfer coefficient can be improved. Increasing the area of the opposing surface 111A upon forming the surface into a rectangular shape will increase the contact area with the refrigerant W. This will further disturb the flow and hence can increase the heat transfer coefficient and improve the cooling performance. As illustrated in FIG. 3, since the opposing surface 111A stands substantially perpendicularly to the sidewall 11, the flow is greatly disturbed, so that the heat transfer coefficient is further improved.

FIG. 4 is a plan sectional view of each fin 1 taken along a cut section perpendicular to the third direction at an intermediate position in the third direction. As illustrated in FIG. 4, a protrusion amount L2 of the protrusion 111 in the second direction is equal to or less than half of an interval L1 between the sidewalls 11 of the fin 1 adjacent in the second direction. Reducing the protrusion amount of the protrusion 111 in this manner makes it possible to prevent clogging with contamination C included in the refrigerant W and suppress an increase in pressure loss. As described above, the protrusion 111 can improve the cooling performance while taking measures against contamination.

Further, since the protrusion 111 is formed by pressing a plate material, as illustrated in FIG. 3, a recess 112 is provided on the side opposite to the protruding direction of the protrusion 111. In this manner, the protrusion 111 can be easily formed by press working. However, the protrusion may be formed by, for example, cutting or welding other than press working.

As illustrated in FIG. 3, the protrusion 111 has a rectangular surface 111B having a rectangular shape continuing toward one side in the first direction with respect to the opposing surface 111A. The rectangular surface 111B is connected to the sidewall 11 at one end in the first direction. When a plate material is pressed to form the protrusion 111, the plate thickness of the connecting portion between the opposing surface 111A and the sidewall 11 becomes thin, but the plate thickness of the connecting portion between the rectangular surface 111B and the sidewall 11 does not become thin. Therefore, having the rectangular surface 111B as described above can reduce processing defects that the protrusion 111 is separated from the sidewall 11 and facilitates press-molding the protrusion 111 to a height close to the plate thickness.

As illustrated in FIG. 4, the protrusions 111 alternately protrude in the second direction toward one side in the first direction. As a result, as illustrated in FIG. 4, the flow of the refrigerant W meanders and the turbulence increases, so that the cooling performance can be improved. However, as illustrated in FIG. 5, the protrusions 111 may protrude in the same direction as the second direction. As a result, the number of processing steps is reduced, and the protrusions 111 are easily manufactured.

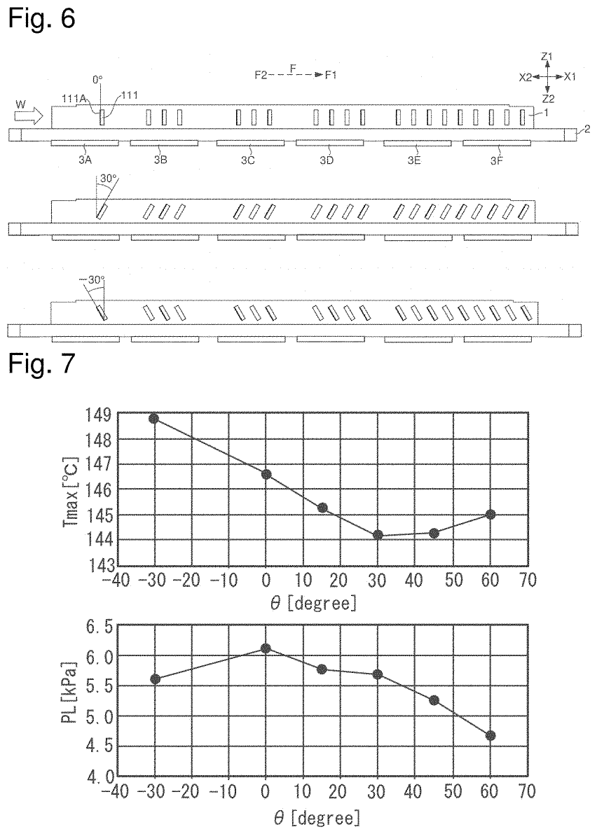

The protrusion 111 may be inclined with respect to the third direction as viewed in the second direction. FIG. 6 is a side view of each of various heat radiators 5 having such a configuration. FIG. 6 illustrates a configuration example in which the inclination angle of the protrusion 111 is changed. Note that, on the uppermost part of FIG. 6, a configuration example of the protrusion 111 that is not inclined is also illustrated.

As illustrated in FIG. 6, the opposing surface 111A of the protrusion 111 is inclined at the inclination angle θ with respect to the third direction as viewed in the second direction. FIG. 6 exemplifies the cases of θ=0°, 30°, and −30°.

FIG. 7 is a graph illustrating an example of the result of performing a simulation on a model having a configuration in which the protrusion 111 is inclined at the inclination angle θ. Referring to FIG. 7, the simulation results of a pressure loss PL and a maximum temperature Tmax of the semiconductor device 3A and the like are plotted.

As in the case of θ=30° illustrated in FIG. 6, when the first-direction other end of the opposing surface 111A is disposed on the base portion 2 side as viewed in the second direction, θ is a positive value. In this case, a reverse pressure gradient is generated near the downstream end of the inclined opposing surface 111A, and the flow of wake stagnates. The flow rate increases on the side opposite to the side where the flow stagnates, that is, near the upstream end (the first-direction other end) of the inclined opposing surface 111A, and the heat transfer coefficient increases. Therefore, the cooling efficiency of the heating elements (the semiconductor device 3A and the like) disposed on the other side of the base portion 2 in the third direction can be improved. In addition, the inclined opposing surface 111A allows the warmed refrigerant W on the base portion 2 side to be guided to one side in the third direction and agitation to occur, so that the refrigerant temperature can be made uniform on the downstream side where the refrigerant temperature on the base portion 2 side tends to be high. Therefore, the cooling efficiency on the downstream side is improved. Furthermore, since the change in the flow direction is reduced by the inclined opposing surface 111A, the pressure loss can be reduced.

In particular, as illustrated in FIG. 7, the inclination angle θ of the opposing surface 111A inclined with respect to the third direction is desirably 15° to 60°. As a result, the cooling performance can be further improved, and the pressure loss can be further reduced.

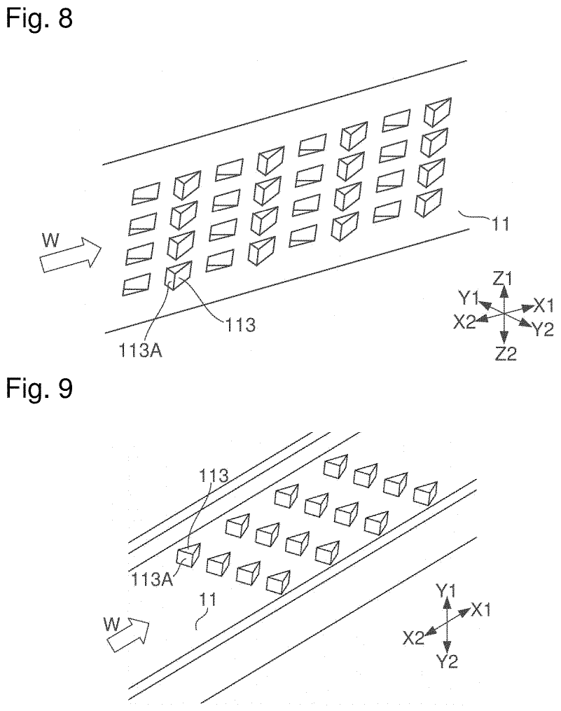

FIG. 8 is an enlarged view illustrating a modification of the protrusions provided on the sidewall 11. The protrusions 113 illustrated in FIG. 8 include a plurality of protrusions disposed in the third direction and a plurality of protrusions in the first direction. That is, the protrusions 111 according to the present modification are divided and disposed in the third direction as compared with the case where one protrusion 113 is disposed in the third direction as in the protrusion described above. Therefore, the change in the direction of the flow is reduced while the occurrence of the turbulence of the flow is maintained, and the pressure loss can be reduced while the cooling performance is maintained. When the density of the number of protrusions is increased until the pressure loss of the pump circulating the refrigerant W reaches the upper limit, the cooling performance can be improved.

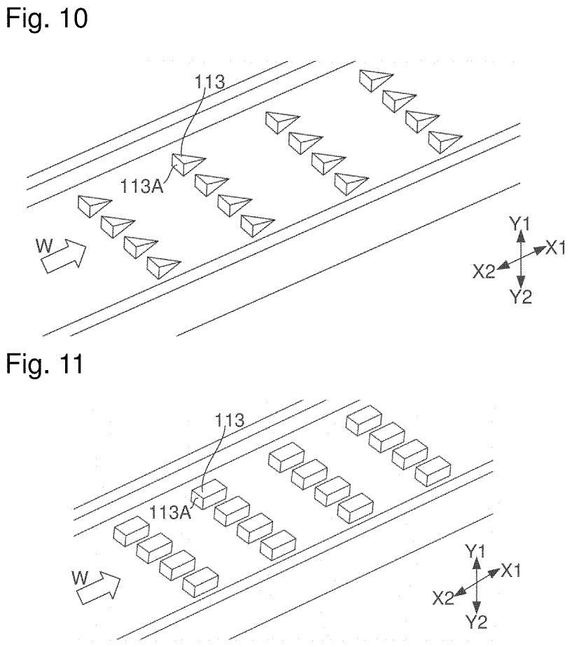

The protrusion 113 illustrated in FIG. 8 is formed in a triangular prism shape extending in the third direction and has a rectangular opposing surface 113A standing substantially vertically from the sidewall 11. However, the shape of the protrusion 113 is not limited to the shape illustrated in FIG. 8 and may have, for example, the configuration illustrated in FIG. 9. The protrusion 113 illustrated in FIG. 9 is formed in a triangular prism shape extending in the second direction and has the rectangular opposing surface 113A. Further, the protrusion 113 illustrated in FIG. 10 may be used. The protrusion 113 is formed in a quadrangular pyramid shape and has the rectangular opposing surface 113A. Further, the protrusion 113 illustrated in FIG. 11 may be used. The protrusion 113 is formed in a rectangular parallelepiped shape and has the rectangular opposing surface 113A.

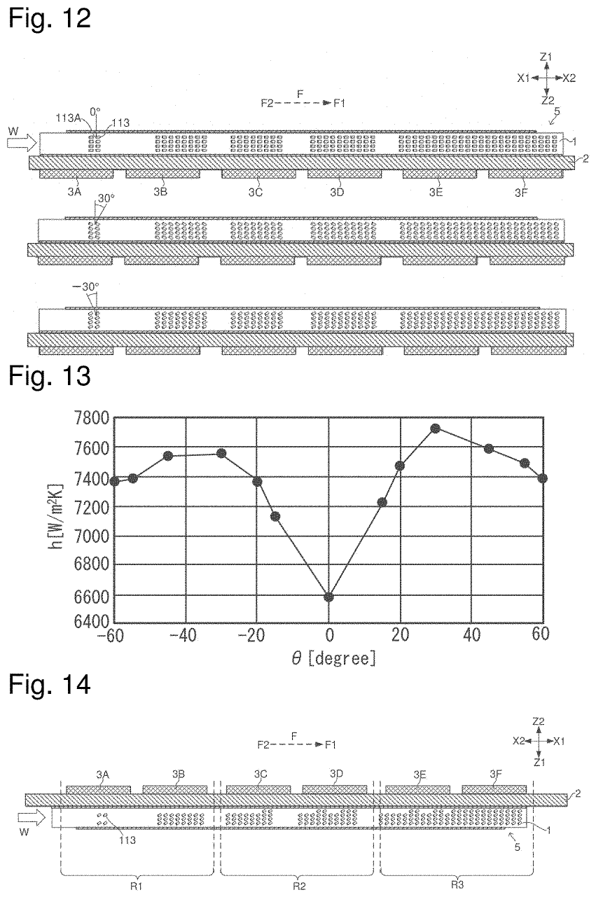

The protrusions 113 divided in the third direction may be inclined with respect to the third direction as viewed in the second direction. FIG. 12 is a side cross-sectional view of each of various heat radiators 5 having such a configuration. FIG. 12 illustrates a configuration example in which the inclination angle of the protrusion 113 is changed. Note that, on the uppermost part of FIG. 12, a configuration example of the protrusion 113 that is not inclined is also illustrated.

As illustrated in FIG. 12, the opposing surface 113A of the protrusion 113 is inclined at the inclination angle θ with respect to the third direction as viewed in the second direction. FIG. 12 exemplifies the cases of θ=0°, 30°, and −30°.

FIG. 13 is a graph illustrating an example of the result of performing a simulation on a model having a configuration in which the protrusion 113 is inclined at the inclination angle θ. Referring to FIG. 13, simulation results of the heat transfer coefficient h are plotted.

As in the case of θ=30° illustrated in FIG. 12, when the first-direction other end of the opposing surface 113A is disposed on the base portion 2 side as viewed in the second direction, θ is a positive value. As illustrated in FIG. 13, the heat transfer coefficient is improved regardless of whether θ is a positive value or negative value. By inclining the opposing surface 113A, a flow to one side in the third direction along the protrusion 113 and a flow to the other side in the third direction occur, a collision occurs between the flows along the protrusion 113 adjacent in the third direction, and the turbulent flow is promoted, so that the cooling performance is improved. In addition, since the refrigerant W can be stirred in the third direction to lower the temperature of the warmed refrigerant W on the base portion 2 side, the cooling performance is improved.

In particular, as illustrated in FIG. 13, the inclination angle θ of the opposing surface 113A inclined with respect to the third direction is preferably −60° to −15° or 15° to 60°. This can further improve the cooling performance.

FIG. 14 is a side cross-sectional view of the heat radiator 5 according to a modification. Referring to FIG. 14, the lower side of the drawing is defined as one side in the third direction.

As illustrated in FIG. 14, regions divided by the same length in the first direction are defined as R1, R2, and R3, and are disposed toward the downstream side in the order of R1, R2, and R3. The number of protrusions 113 increases in the order of R1, R2, and R3. That is, the number of protrusions 113 for each of the regions R1, R2, and R3 divided by the same length in the first direction increases toward one side in the first direction. When the protrusions 113 are provided, the cooling performance of the fin 1 is improved, but this leads to an increase in pressure loss. The temperature of the refrigerant W tends to be higher on the downstream side than on the upstream side and the temperature of the heating element tends to be higher. Accordingly, as described above, reducing the installation density of the protrusions 113 on the upstream side and increasing the installation density toward the downstream side makes it possible to reduce the pressure loss while suppressing the maximum temperature of the heating elements (semiconductor device 3A or the like) to be low. In addition, since the temperature difference between the heating elements (the semiconductor device 3A and the like) disposed in the first direction can be suppressed, the warpage of the base portion 2 caused by the temperature difference can be suppressed.

As illustrated in FIG. 14, in each of the regions R1, R2, and R3, the number of protrusions 113 disposed in the first direction is the smallest on the base portion 2 side. Referring to FIG. 14, the number of protrusions closest to the base portion 2 is 0 in the region R1, 7 in the region R2, and 16 in the region R3. By reducing the protrusions 113 near the base portion 2, the flow path resistance near the base portion 2 is reduced, and the flow velocity is increased. The number of protrusions 113 in the region on the downstream side is large, and the refrigerant W having an increased flow velocity collides with the protrusions 113 near the base portion 2, so that the temperature of the downstream heating element (semiconductor device 3F) having the highest temperature can be lowered.

The example embodiment of the present disclosure has been described above. The scope of the present disclosure is not limited to the above example embodiment. The present disclosure can be implemented by making various changes to the above example embodiment without departing from the gist of the disclosure. The above example embodiment describes matters that can be optionally combined together, as appropriate, as long as there is no inconsistency.

As described above, for example, a heat radiator according to an aspect of the present disclosure includes a plate-shaped base portion that extends in a first direction along a flowing direction of a refrigerant and in a second direction orthogonal to the first direction and has a thickness in a third direction orthogonal to the first direction and the second direction, and a fin that protrudes from the base portion to one side in the third direction. The fin has a flat plate-shaped sidewall that extends in the first direction and the third direction with the second direction being a thickness direction. The sidewall is provided with a protrusion protruding in the second direction. The protrusion amount of the protrusion in the second direction is equal to or less than half of the interval between the sidewalls of the fin adjacent to each other in the second direction. The protrusion has an opposing surface facing the flowing direction of the refrigerant. The opposing surface has a rectangular shape standing in the second direction from the sidewall (first configuration).

In the first configuration, a recess may be provided on the side opposite to the protruding direction of the protrusion (second configuration).

In the second configuration, the protrusion has a rectangular surface continuing toward one side in the first direction with respect to the opposing surface, and the rectangular surface may be connected to the sidewall at one end in the first direction (third configuration).

In any one of the first to third configurations, the protrusions includes one protrusion disposed in the third direction and a plurality of protrusions disposed in the first direction. The opposing surface is inclined with respect to the third direction as viewed in the second direction. The first-direction other end of the opposing surface may be disposed on the base portion side as viewed in the second direction (fourth configuration).

In the fourth configuration, the inclination angle of the opposing surface inclined with respect to the third direction may be 15° to 60° (fifth configuration).

In any one of the first to third configurations, the protrusions may include a plurality of protrusions disposed in the third direction and a plurality of the protrusions disposed in the first direction (sixth configuration).

In the sixth configuration, the opposing surface may be inclined with respect to the third direction as viewed in the second direction (seventh configuration).

In the seventh configuration, the inclination angle of the opposing surface inclined with respect to the third direction may be −60° to −15° or 15° to 60° (eighth configuration).

In any one of the sixth to eighth configurations, the number of protrusions for each of the regions divided by the same length in the first direction may increase toward one side in the first direction (ninth configuration).

In the ninth configuration, in each of the regions, the number of the protrusions disposed in the first direction may be the smallest on the base portion side (10th configuration).

In any one of the first to 10th configurations, the protrusions may include a plurality of protrusions disposed in the first direction and alternately protruding in the second direction toward one side in the first direction (11th configuration).

In any one of the first to 10th configurations, the protrusions may include a plurality of protrusions disposed in the first direction and protruding in the same direction as the second direction (12th configuration).

A semiconductor module according to an aspect of the present disclosure includes the heat radiator having any one of the first to 12th configurations and a semiconductor device disposed on the other side of the base portion in the third direction (13th configuration).

The present disclosure can be used for cooling various types heating elements.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat radiator comprising:
a plate-shaped base portion that extends in a first direction along a flowing direction of a refrigerant and in a second direction perpendicular or substantially perpendicular to the first direction and has a thickness in a third direction perpendicular or substantially perpendicular to the first direction and the second direction; and
a fin that protrudes from the base portion to one side in the third direction; wherein
the fin includes a flat plate-shaped sidewall that extends in the first direction and the third direction with the second direction being a thickness direction;
the sidewall is provided with a protrusion protruding in the second direction;
a protruding amount of the protrusion in the second direction is not more than about one half of an interval between the sidewalls of the fin adjacent to each other in the second direction;
the protrusion includes an opposing surface opposing the flowing direction of the refrigerant; and
the opposing surface has a rectangular or substantially rectangular shape extending in the second direction from the sidewall.

2. The heat radiator according to claim 1, wherein a recess is provided on a side opposite to a protruding direction of the protrusion.

3. The heat radiator according to claim 2, wherein
the protrusion includes a rectangular or substantially rectangular surface continuing toward one side in the first direction with respect to the opposing surface; and
the rectangular or substantially rectangular surface is connected to the sidewall at one end in the first direction.

4. The heat radiator according to claim 1, wherein
a plurality of the protrusions is provided and the plurality of protrusions includes one protrusion located in the third direction and multiple protrusions located in the first direction;
the opposing surface is inclined with respect to the third direction as viewed in the second direction; and
a first-direction other end of the opposing surface is on the base portion side as viewed in the second direction.

5. The heat radiator according to claim 4, wherein an inclination angle of the opposing surface inclined with respect to the third direction is about 15° to about 60°.

6. The heat radiator according to claim 1, wherein the protrusion includes a plurality of protrusions located in the third direction and a plurality of protrusions located in the first direction.

7. The heat radiator according to claim 6, wherein the opposing surface is inclined with respect to the third direction as viewed in the second direction.

8. The heat radiator according to claim 7, wherein an inclination angle of the opposing surface inclined with respect to the third direction is about −60° to about −15° or about 15° to about 60°.

9. The heat radiator according to claim 6, wherein a number of the protrusions for each of regions divided by a same length in the first direction increases toward one side in the first direction.

10. The heat radiator according to claim 9, wherein a number of the protrusions located in the first direction in each of the regions is a smallest on the base portion side.

11. The heat radiator according to claim 1, wherein the protrusion includes a plurality of protrusions located in the first direction and alternately protruding in the second direction toward one side in the first direction.

12. The heat radiator according to claim 1, wherein the protrusion includes a plurality of protrusions located in the first direction and protruding in the same direction in the second direction.

13. A semiconductor module comprising:
the heat radiator according to claim 1; and
a semiconductor device on another side of the base portion in the third direction.
